(19) United States
(12) Patent Application Publication
(10) Pub. No.: US 2026/0090001 A1
(43) Pub. Date: Mar. 26, 2026

(54) NITRIDE-BASED SEMICONDUCTOR DEVICE AND METHOD FOR MANUFACTURING THEREOF

(71) Applicant: INNOSCIENCE (SUZHOU) SEMICONDUCTOR CO., LTD., Suzhou, Jiangsu (CN)

(72) Inventors: Ronghui HAO, Suzhou, Jiangsu (CN); King Yuen WONG, Suzhou, Jiangsu (CN)

(73) Assignee: INNOSCIENCE (SUZHOU) SEMICONDUCTOR CO., LTD., Suzhou, Jiangsu (CN)

(21) Appl. No.: 19/112,584

(22) PCT Filed: Sep. 22, 2022
(86) PCT No.: PCT/CN2022/120410

§ 371 Date: Mar. 17, 2025

(51) Int. Cl. H10D 30/47; H10D 30/01; H10D 62/10; H10D 62/60; H10D 62/824

(52) U.S. Cl. CPC H10D 30/475; H10D 30/015; H10D 62/60; H10D 62/824; H10D 62/103

(57) ABSTRACT

A nitride-based semiconductor device includes a first III-V nitride-based semiconductor layer, a second III-V nitride-based semiconductor layer, a source electrode and a drain electrode, and a doped nitride-based semiconductor layer. The second III-V nitride-based semiconductor layer is disposed over the first III-V nitride-based semiconductor layer and has a bandgap higher than a bandgap of the first III-V nitride-based semiconductor layer. The source electrode and the drain electrode are disposed over the second III-V nitride-based semiconductor layer. The doped nitride-based semiconductor layer is disposed over the second III-V nitride-based semiconductor layer and between the source electrode and the drain electrode, in which the doped nitride-based semiconductor layer has an aluminum concentration increasing along an upward direction. The gate electrode is disposed over the doped nitride-based semiconductor layer.

### CROSS-REFERENCE TO RELATED APPLICATIONS

This application is a national stage of international PCT application No. PCT/CN2022/120410 filed on Sep. 22, 2022, the entire contents of which are incorporated herein by reference.

### FIELD

The present disclosure generally relates to a nitride-based semiconductor device. More specifically, the present disclosure relates to a nitride-based semiconductor device having an element-varied III-V layer beneath a gate electrode.

### BACKGROUND

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET).

### SUMMARY

In accordance with one aspect of the present disclosure, a nitride-based semiconductor device is provided. The nitride-based semiconductor device includes a first III-V nitride-based semiconductor layer, a second III-V nitride-based semiconductor layer, a source electrode and a drain electrode, and a doped nitride-based semiconductor layer. The second III-V nitride-based semiconductor layer is disposed over the first III-V nitride-based semiconductor layer and has a bandgap higher than a bandgap of the first III-V nitride-based semiconductor layer. The source electrode and the drain electrode are disposed over the second III-V nitride-based semiconductor layer. The doped nitride-based semiconductor layer is disposed over the second III-V nitride-based semiconductor layer and between the source electrode and the drain electrode, in which the doped nitride-based semiconductor layer has an aluminum concentration increasing along an upward direction. The gate electrode is disposed over the doped nitride-based semiconductor layer.

In accordance with one aspect of the present disclosure, a method for manufacturing a nitride-based semiconductor device is provided. The method includes steps as follows: forming a first III-V nitride-based semiconductor layer over a substrate; forming a second III-V nitride-based semiconductor layer over the first III-V nitride-based semiconductor layer; forming a doped nitride-based semiconductor layer over the second III-V nitride-based semiconductor layer, wherein the doped nitride-based semiconductor layer has an aluminum concentration increasing along an upward direction; and forming a gate electrode on the doped nitride-based semiconductor layer.

In accordance with one aspect of the present disclosure, a nitride-based semiconductor device is provided. The nitride-based semiconductor device includes a first III-V nitride-based semiconductor layer, a second III-V nitride-based semiconductor layer, a source electrode and a drain electrode, and a doped nitride-based semiconductor layer. The second III-V nitride-based semiconductor layer is disposed over the first III-V nitride-based semiconductor layer and has a bandgap higher than a bandgap of the first III-V nitride-based semiconductor layer. The doped nitride-based semiconductor layer is disposed over the second III-V nitride-based semiconductor layer, in which the doped nitride-based semiconductor layer has a bottom surface devoid of aluminum and a top surface comprising aluminum.

By the above configuration, the increase in the aluminum concentration can make a bandgap difference between the doped nitride-based semiconductor layer and the second nitride-based semiconductor layer varied gradually, such that the bandgap difference therebetween is not constant. The gradually varied bandgap difference can induce polarization doping, which results in generation of polarized charges. The polarized charges include holes to further improve hole concentration of the doped nitride-based semiconductor layer, thereby enhancing device threshold voltage.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1A is a vertical view of a semiconductor device according to some embodiments of the present disclosure;

FIG. 1B shows compositional changes in a doped nitride-based semiconductor layer according to some embodiments of the present disclosure;

FIG. 1C shows a graph of a relationship between concentration ratio and thickness of a doped nitride-based semiconductor layer according to some embodiments of the present disclosure;

FIG. 2A is a vertical cross-sectional view of a doped nitride-based semiconductor layer according to some embodiments of the present disclosure; and

FIG. 2B shows a graph of a relationship between concentration ratio and thickness of a doped nitride-based semiconductor layer according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “on,” “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

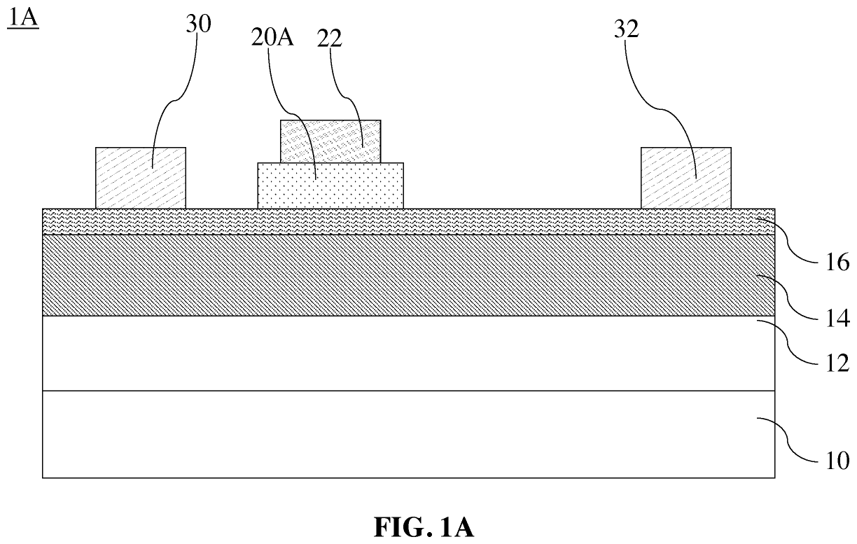

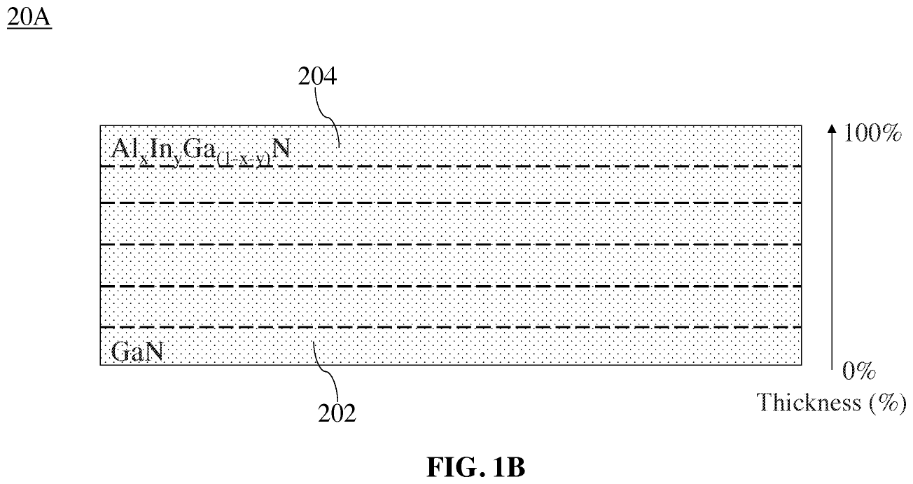

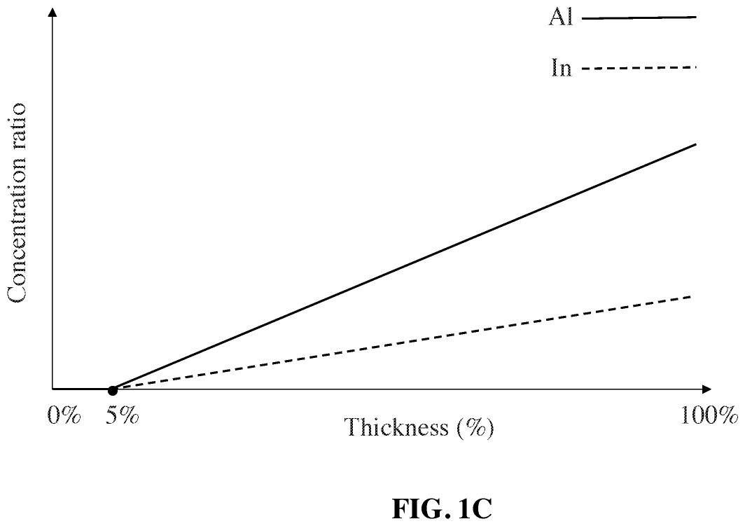

FIG. 1A is a vertical view of a semiconductor device 1A according to some embodiments of the present disclosure. The nitride-based semiconductor device 1A includes a substrate 10, a buffer layer 12, nitride-based semiconductor layers 14, 16, a doped nitride-based semiconductor layer 20A, a gate electrode 22, and electrodes 30 and 32.

The substrate 10 may be a semiconductor substrate. The exemplary materials of the substrate 10 can include, for example but are not limited to, Si, SiGe, SiC, gallium arsenide, p-doped Si, n-doped Si, sapphire, semiconductor on insulator, such as silicon on insulator (SOI), or other suitable substrate materials. In some embodiments, the substrate 10 can include, for example, but is not limited to, group III elements, group IV elements, group V elements, or combinations thereof (e.g., III-V compounds). In other embodiments, the substrate 10 can include, for example but is not limited to, one or more other features, such as a doped region, a buried layer, an epitaxial (epi) layer, or combinations thereof.

The buffer layer 12 can be disposed on/over/above the substrate 10. The buffer layer 12 can be disposed between the substrate 10 and the nitride-based semiconductor layer 14. The buffer layer 12 can be configured to reduce lattice and thermal mismatches between the substrate 10 and the nitride-based semiconductor layer 14, thereby curing defects due to the mismatches/difference. The buffer layer 12 may include a III-V compound. The III-V compound can include, for example but are not limited to, aluminum, gallium, indium, nitrogen, or combinations thereof. Accordingly, the exemplary materials of the buffer layer can further include, for example but are not limited to, GaN, AIN, AlGaN, InAlGaN, or combinations thereof.

In some embodiments, the semiconductor device 1A may further include a nucleation layer (not shown). The nucleation layer may be formed between the substrate 10 and the buffer layer 12. The nucleation layer can be configured to provide a transition to accommodate a mismatch/difference between the substrate 10 and a III-nitride layer of the buffer layer 12. The exemplary material of the nucleation layer can include, for example but is not limited to AlN or any of its alloys.

The nitride-based semiconductor layer 14 can be disposed on/over/above the buffer layer 12. The nitride-based semiconductor layer 14 can make contact with the buffer layer 12. The nitride-based semiconductor layer 16 can be disposed on/over/above the nitride-based semiconductor layer 14. The nitride-based semiconductor layer 16 can get contact with the nitride-based semiconductor layer 14. The nitride-based semiconductor layer 14 may be a first III-V nitride-based semiconductor layer. The nitride-based semiconductor layer 16 may be a second III-V nitride-based semiconductor layer.

The exemplary materials of the nitride-based semiconductor layer 14 can include, for example but are not limited to, nitrides or group III-V compounds, such as GaN, AlN, InN, InₓAl_{y}Ga_{(1-x-y)}N where x+y≤1, Al_{y}Ga_{(1-y)}N where y≤1. The exemplary materials of the nitride-based semiconductor layer 16 can include, for example but are not limited to, nitrides or group III-V compounds, such as GaN, AlN, InN, InₓAl_{y}Ga_{(1-x-y)}N where x+y≤1, Al_{y}Ga_{(1-y)}N where y≤1.

The exemplary materials of the nitride-based semiconductor layers 14 and 16 are selected such that the nitride-based semiconductor layer 16 has a bandgap (i.e., forbidden band width) greater/higher than a bandgap of the nitride-based semiconductor layer 14, which causes electron affinities thereof different from each other and forms a heterojunction therebetween. For example, when the nitride-based semiconductor layer 14 is an undoped GaN layer having a bandgap of approximately 3.4 eV, the nitride-based semiconductor layer 16 can be selected as an AlGaN layer having bandgap of approximately 4.0 eV. As such, the nitride-based semiconductor layers 14 and 16 can serve as a channel layer and a barrier layer, respectively. A triangular well potential is generated at a bonded interface between the channel and barrier layers, so that electrons accumulate in the triangular well, thereby generating a two-dimensional electron gas (2DEG) region adjacent to the heterojunction. Accordingly, the semiconductor device 1A is available to include at least one GaN-based high-electron-mobility transistor (HEMT).

The electrodes 30 and 32 are disposed on the nitride-based semiconductor layer 16. The electrodes 30 and 32 can make contact with the nitride-based semiconductor layer 16. The electrode 30 can serve as a source electrode or a drain electrode. The electrode 32 can serve as a source electrode or a drain electrode.

In some embodiments, each of the electrodes 30 and 32 includes one or more conformal conductive layers. In some embodiments, the electrodes 30 and 32 can include, for example but are not limited to, metals, alloys, doped semiconductor materials (such as doped crystalline silicon), other conductor materials, or combinations thereof. The exemplary materials of the electrodes 30 and 32 can include, for example but are not limited to, Ti, AlSi, TiN, or combinations thereof. In some embodiments, each of the electrodes 30 and 32 forms ohmic contact with the nitride-based semiconductor layer 16. The ohmic contact can be achieved by applying Ti, Al, or other suitable materials to the electrodes 30 and 32.

The doped nitride-based semiconductor layer 20A and the gate electrode 22 are stacked on the nitride-based semiconductor layer 16. The doped nitride-based semiconductor layer 20A is located between the nitride-based semiconductor layer 16 and the gate electrode 22. The doped nitride-based semiconductor layer 20A and the gate electrode 22 are located between the electrodes 30 and 32. The electrodes 30 and 32 are located at two opposite sides of the gate electrode 22 (i.e., the gate electrode 22 is located between the electrodes 30 and 32). The doped nitride-based semiconductor layer 20A, the gate electrode 22 and the electrodes 30 and 32 can collectively act as a GaN-based HEMT with the 2DEG region.

The semiconductor device 1A can be designed as being an enhancement mode device, which is in a normally-off state when the gate electrode 22 is at approximately zero bias. In other words, when no voltage is applied to the gate electrode 22 or a voltage applied to the gate electrode 22 is less than a threshold voltage (i.e., a minimum voltage required to form an inversion layer below the gate electrode 22), the zone of the 2DEG region below the gate electrode 22 is kept blocked, and thus no current flows therethrough.

In some embodiments, the gate electrode 22 may include metals or metal compounds. The exemplary materials of the metals or metal compounds can include, for example but are not limited to, W, Au, Pd, Ti, Ta, Co, Ni, Pt, Mo, TiN, TaN, metal alloys thereof, or other metallic compounds. In some embodiments, the exemplary materials of the gate electrode 22 may include, for example but are not limited to, nitrides, oxides, silicides, doped semiconductors, or combinations thereof. In some embodiments, the optional dielectric layer can be formed by a single layer or more layers of dielectric materials. The exemplary dielectric materials can include, for example but are not limited to, one or more oxide layers, a SiOx layer, a SiNx layer, a high-k dielectric material (e.g., HfO₂, Al₂O₃, TiO₂, HfZrO, Ta₂O₃, HfSiO₄, ZrO₂, ZrSiO₂, etc.), or combinations thereof.

Regarding the materials of the doped nitride-based semiconductor layer 20A, there are two issues to be considered. The first one is defect. For example, as a condition that P-GaN layer doped with Mg is selected as a doped nitride-based semiconductor layer, the doping concentration of the acceptor impurity Mg of p-GaN is extremely high. The higher the doping concentration is, the more defects are in the material, which lets the reliability risk raised. The second one is the activation energy of the acceptor impurity is high, resulting in a low activation rate (e.g., 1%) as well as difficulty in improvement to device threshold voltage. To solve such issues, the present disclosure is provided with a novel structure.

FIG. 1B shows compositional changes in a doped nitride-based semiconductor layer 20A according to some embodiments of the present disclosure. FIG. 1C shows a graph of a relationship between concentration ratio and thickness of a doped nitride-based semiconductor layer 20A according to some embodiments of the present disclosure. In FIG. 1C, the x axis represents a thickness of a doped nitride-based semiconductor layer with a unit of percentage (i.e., 0% is the bottom most surface and 100% is the topmost surface); and the y axis represents a concentration ratio with arbitrary unit.

The exemplary materials of the doped nitride-based semiconductor layer 20A can include, for example but are not limited to, gallium, aluminum, indium, nitrogen. The doped nitride-based semiconductor layer 20A may be formed as p-doped group III-V nitride semiconductor materials. In some embodiments, the doped nitride-based semiconductor layer 20A includes p-type impurity, such as Be, Mg, Zn, Cd.

The doped nitride-based semiconductor layer 20A has an aluminum concentration increasing along an upward direction. The doped nitride-based semiconductor layer 20A has an indium concentration increasing along the upward direction. More specifically, the doped nitride-based semiconductor layer 20A has a bottom surface made from binary composition and a top surface made from quaternary composition. The changes of the composition from binary composition to quaternary composition can be achieved by increase in the aluminum concentration and the indium concentration.

In the exemplary illustration of FIG. 1B, the doped nitride-based semiconductor layer 20A transitions from GaN at a bottom surface thereof to AlₓIn_{y}Ga_{(1-x-y)}N at a top surface thereof. That is, the binary composition and the quaternary composition as afore-mentioned can be GaN and AlₓIn_{y}Ga_{(1-x-y)}N.

Referring to FIG. 1C, the increase in the aluminum concentration can make a bandgap difference between the doped nitride-based semiconductor layer 20A and the nitride-based semiconductor layer 16 (see. FIG. 1A) varied gradually, such that the bandgap difference therebetween is not constant. The gradually varied bandgap difference can induce polarization doping, which results in generation of polarized charges. The polarized charges can include holes to further improve hole concentration of the doped nitride-based semiconductor layer 20A, thereby enhancing device threshold voltage. Since the hole concentration of the doped nitride-based semiconductor layer 20A can be improved by the gradually varied bandgap difference, the required doping concentration of the acceptor impurity Mg of the doped nitride-based semiconductor layer 20A can get reduced, thereby improving the device reliability. Accordingly, the defect density is reduced as well.

In order to further enhance the device stability, indium is introduced into the doped nitride-based semiconductor layer 20A accordingly. The introduction of indium into the doped nitride-based semiconductor layer 20A can suppress potential relaxation in the doped nitride-based semiconductor layer 20A. Relaxation in a III-V nitride-based semiconductor layer may result in restriction to generation of polarized charge. The relaxation occurs as a III-V nitride-based semiconductor layer becomes thicker. Moreover, as the doped nitride-based semiconductor layer 20A is formed by applying the quaternary composition such as AlInGaN, the stress of the doped nitride-based semiconductor layer 20A is easy to adjust.

As shown in the graph of FIG. 1C, the aluminum concentration and the indium concentration approach about 0% below about 5% thickness. Accordingly, the doped nitride-based semiconductor layer 20A may have a gallium concentration in constant within a portion of the doped nitride-based semiconductor layer 20A with 5% of the thickness from the bottom surface. At about 5% thickness, the indium concentration and the aluminum concentration start increasing. That is, the indium concentration and the aluminum concentration may start to increase at the same elevation within a thickness of the doped nitride-based semiconductor layer 20A.

In some embodiments, to obtain desired layer characteristic, an increase rate of the indium concentration is slower than an increase rate of the aluminum concentration. Accordingly, the indium concentration is less than the aluminum concentration at the top surface of the doped nitride-based semiconductor layer 20A. The desired layer characteristic may include layer stress, layer lattice constant, or the likes. Eventually, with respect to the doped nitride-based semiconductor layer 20A, the bottom surface thereof (i.e., at 0% thickness) is devoid of aluminum and indium, and the top surface thereof (i.e., at 100% thickness) includes aluminum and indium.

To run a method for manufacturing the nitride-based semiconductor device 1A, receipts for the doped nitride-based semiconductor layer 20A can be turned. In the following descriptions, deposition techniques can include, for example but are not limited to, atomic layer deposition (ALD), physical vapor deposition (PVD), chemical vapor deposition (CVD), metal organic CVD (MOCVD), plasma enhanced CVD (PECVD), low-pressure CVD (LPCVD), plasma-assisted vapor deposition, epitaxial growth, or other suitable processes.

In the method, the buffer layer 12 is formed on the substrate 10. The III-V nitride-based semiconductor layer 14 is formed over the buffer layer 12 and the substrate 10, and then the III-V nitride-based semiconductor layer 16 is formed over the III-V nitride-based semiconductor layer 14. The doped nitride-based semiconductor layer 20A is formed over the III-V nitride-based semiconductor layer 16. During a deposition process for the growth of the doped nitride-based semiconductor layer 20A, aluminum, indium, gallium, and nitrogen precursors can be selected to introduce into a gas flow in a chamber, and the ratio among them is adjustable, so as to achieve the composition as above. Thereafter, electrodes such as the electrodes 30 and 32, the gate electrode 22 as afore mentioned are formed over the structure.

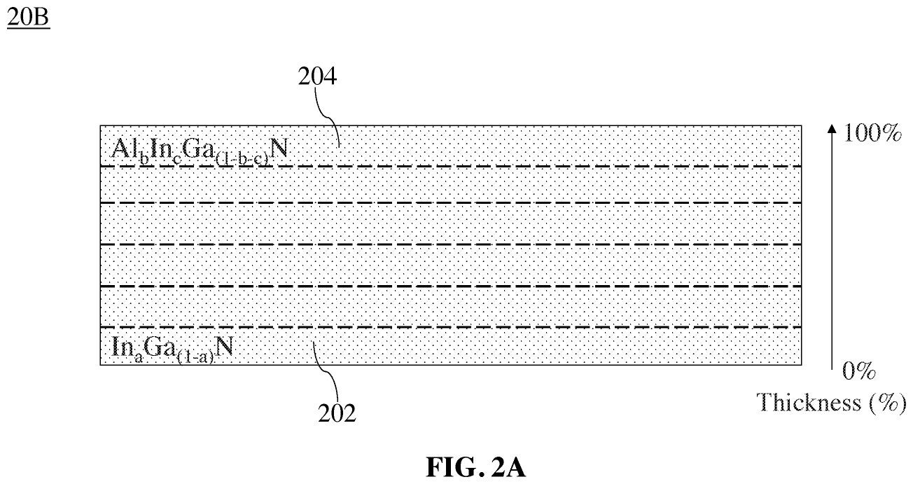

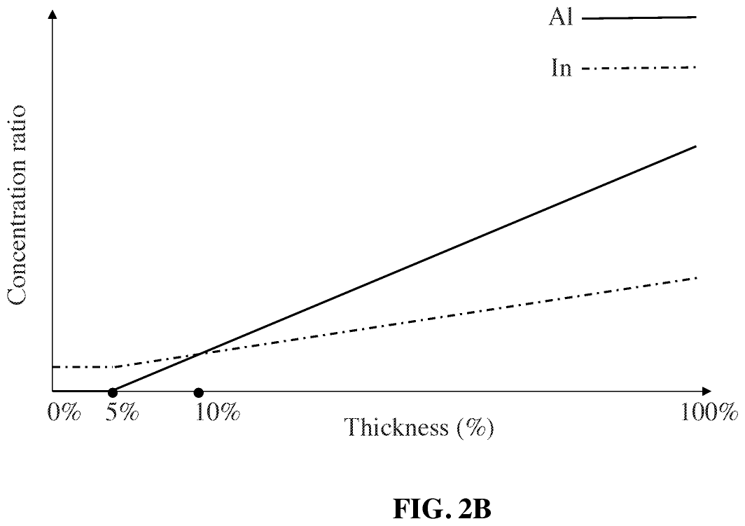

FIG. 2A is a vertical cross-sectional view of a doped nitride-based semiconductor layer 20B according to some embodiments of the present disclosure. FIG. 2B shows a graph of a relationship between concentration ratio and thickness of a doped nitride-based semiconductor layer 20B according to some embodiments of the present disclosure. In FIG. 2B, the x axis represents a thickness of a doped nitride-based semiconductor layer with a unit of percentage (i.e., 0% is the bottom most surface and 100% is the top most surface); and the y axis represents a concentration ratio with arbitrary unit.

The doped nitride-based semiconductor layer 20B is similar to the doped nitride-based semiconductor layer 20A as described and illustrated with reference to FIGS. 1A-1C, except that the doped nitride-based semiconductor layer 20B has a different composition than the doped nitride-based semiconductor layer 20A.

As shown in the exemplary illustration of FIG. 2A, the exemplary materials of the doped nitride-based semiconductor layer 20B can include, for example but are not limited to, gallium, aluminum, indium, nitrogen. The doped nitride-based semiconductor layer 20B may be formed as p-doped group III-V nitride semiconductor materials. In some embodiments, the doped nitride-based semiconductor layer 20B includes p-type impurity, such as Be, Mg, Zn, Cd.

The doped nitride-based semiconductor layer 20B has an aluminum concentration increasing along an upward direction. The doped nitride-based semiconductor layer 20B has an indium concentration increasing along the upward direction. More specifically, the doped nitride-based semiconductor layer 20B has a bottom surface made from ternary composition and a top surface made from quaternary composition. The changes of the composition from ternary composition to quaternary composition can be achieved by an increase in the aluminum concentration and the indium concentration.

In the exemplary illustration of FIG. 2A, the doped nitride-based semiconductor layer 20B transitions from InₐGa₍₁₋ₐ₎N at a bottom surface thereof to Al_{b}In_{c}Ga_{(1-b-c)}N at a top surface thereof. That is, the ternary composition and the quaternary composition as afore-mentioned can be InₐGa₍₁₋ₐ₎N and Al_{b}In_{c}Ga_{(1-b-c)}N.

The increase in the aluminum concentration can make a bandgap difference between the doped nitride-based semiconductor layer 20B and the barrier layer varied gradually, such that the bandgap difference therebetween is not constant, which can achieve the positive effect as afore mentioned. In order to further enhance the device stability, indium is introduced into the doped nitride-based semiconductor layer 20B accordingly.

As shown in the graph of FIG. 2B, the doped nitride-based semiconductor layer 20B has an indium concentration greater than an aluminum concentration at the bottom surface of the doped nitride-based semiconductor layer 20B. The indium concentration is greater than the aluminum concentration within a portion of the doped nitride-based semiconductor layer 20B with 5% of the thickness from the bottom surface. In some embodiments, the indium concentration is almost constant from 0% to 5% thickness.

At about 5% thickness, the indium concentration and the aluminum concentration start increasing. That is, the indium concentration and the aluminum concentration may start to increase at the same elevation within a thickness of the doped nitride-based semiconductor layer 20B. In some embodiments, an increase rate of the indium concentration is slower than an increase rate of the aluminum concentration. The indium concentration is almost the same as the aluminum concentration at about 10% thickness, and the aluminum concentration is greater than the indium concentration after 10% thickness. For example, the indium concentration is less than the aluminum concentration at the top surface of the doped nitride-based semiconductor layer 20B.

Such the composition is made for modulation to layer stress. Eventually, with respect to the doped nitride-based semiconductor layer 20B, the bottom surface thereof (i.e., at 0% thickness) is devoid of aluminum but includes indium, and the top surface thereof (i.e., at 100% thickness) includes aluminum and indium.

The embodiments were chosen and described in order to best explain the principles of the disclosure and its practical application, thereby enabling others skilled in the art to understand the disclosure for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to +5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 A μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A nitride-based semiconductor device comprising:
a first III-V nitride-based semiconductor layer;
a second III-V nitride-based semiconductor layer disposed over the first III-V nitride-based semiconductor layer and having a bandgap higher than a bandgap of the first III-V nitride-based semiconductor layer;
a source electrode and a drain electrode disposed over the second III-V nitride-based semiconductor layer;
a doped nitride-based semiconductor layer disposed over the second III-V nitride-based semiconductor layer and between the source electrode and the drain electrode, wherein the doped nitride-based semiconductor layer has an aluminum concentration increasing along an upward direction; and
a gate electrode disposed over the doped nitride-based semiconductor layer.

2. The nitride-based semiconductor device of claim 1, wherein the doped nitride-based semiconductor layer has a bottom surface made from binary composition.

3. The nitride-based semiconductor device of claim 1, wherein the doped nitride-based semiconductor layer has a bottom surface made from ternary composition.

4. The nitride-based semiconductor device of claim 1, wherein the doped nitride-based semiconductor layer has a top surface made from quaternary composition.

5. The nitride-based semiconductor device of claim 4, wherein the quaternary composition comprises AlₓIn_{y}Ga_{(1-x-y)}N.

6. The nitride-based semiconductor device of claim 1, wherein the doped nitride-based semiconductor layer comprises indium.

7. The nitride-based semiconductor device of claim 1, wherein the doped nitride-based semiconductor layer has an indium concentration greater than the aluminum concentration at a bottom surface of the doped nitride-based semiconductor layer.

8. The nitride-based semiconductor device of claim 7, wherein the indium concentration is greater than the aluminum concentration within a portion of the doped nitride-based semiconductor layer with 5% of a thickness of the doped nitride-based semiconductor layer from the bottom surface.

9. The nitride-based semiconductor device of claim 7, wherein the indium concentration is less than the aluminum concentration at a top surface of the doped nitride-based semiconductor layer.

10. The nitride-based semiconductor device of claim 1, wherein the doped nitride-based semiconductor layer further has an indium concentration increasing along the upward direction.

11. The nitride-based semiconductor device of claim 10, wherein the indium concentration and the aluminum concentration start increasing at the same elevation within a thickness of the doped nitride-based semiconductor layer.

12. The nitride-based semiconductor device of claim 10, wherein an increase rate of the indium concentration is slower than an increase rate of the aluminum concentration.

13. The nitride-based semiconductor device of claim 1, wherein the doped nitride-based semiconductor layer has a gallium concentration in constant within a portion of the doped nitride-based semiconductor layer with 5% of a thickness of the doped nitride-based semiconductor layer from a bottom surface of the doped nitride-based semiconductor layer.

14. The nitride-based semiconductor device of claim 1, wherein the doped nitride-based semiconductor layer comprises GaN at a bottom surface thereof, and the doped nitride-based semiconductor layer further has an indium concentration increasing along the upward direction, such that the doped nitride-based semiconductor layer comprises AlInGaN at a top surface thereof.

15. The nitride-based semiconductor device of claim 1, wherein the doped nitride-based semiconductor layer comprises InGaN at a bottom surface thereof, and the doped nitride-based semiconductor layer further has an indium concentration increasing along the upward direction, such that the doped nitride-based semiconductor layer comprises AlInGaN at a top surface thereof.

16. A method for manufacturing a nitride-based semiconductor device, comprising:
forming a first III-V nitride-based semiconductor layer over a substrate;
forming a second III-V nitride-based semiconductor layer over the first III-V nitride-based semiconductor layer;
forming a doped nitride-based semiconductor layer over the second III-V nitride-based semiconductor layer, wherein the doped nitride-based semiconductor layer has an aluminum concentration increasing along an upward direction; and
forming a gate electrode on the doped nitride-based semiconductor layer.

17. The method of claim 16, wherein the doped nitride-based semiconductor layer has a bottom surface made from binary composition or ternary composition.

18. (canceled)

19. The method of claim 16, wherein the doped nitride-based semiconductor layer has a top surface made from quaternary composition.

20. The method of claim 19, wherein the quaternary composition comprises AlₓIn_{y}Ga_{(1-x-y)}N.

21. A nitride-based semiconductor device comprising:
a first III-V nitride-based semiconductor layer;
a second III-V nitride-based semiconductor layer disposed over the first III-V nitride-based semiconductor layer and having a bandgap higher than a bandgap of the first III-V nitride-based semiconductor layer; and
a doped nitride-based semiconductor layer disposed over the second III-V nitride-based semiconductor layer, wherein the doped nitride-based semiconductor layer has a bottom surface devoid of aluminum and a top surface comprising aluminum.

22-25. (canceled)
